(19) United States
(12) Patent Application Publication
(10) Pub. No.: US 2020/0324386 A1
(43) Pub. Date: Oct. 15, 2020

(54) SEGMENT DESIGNS FOR DISCS

(71) Applicant: ENTEGRIS, INC., Billerica, MA (US)

(72) Inventors: Doruk YENER, Bedford, MA (US); Conrad SURIAGA, Andover, MA (US); Joseph SOUSA, Lakeville, MA (US); Laundy OEUR, Nashua, NH (US); Joseph RIVERS, Austin, TX (US); Elango BALU, Lawrence, MA (US)

(21) Appl. No.: 16/843,135

(22) Filed: Apr. 8, 2020

Related U.S. Application Data
(60) Provisional application No. 62/831,544, filed on Apr. 9, 2019.

(51) Int. Cl. B24B 53/017; B24B 53/12

(52) U.S. Cl. CPC B24B 53/017; H01L 21/304; B24B 53/12

(57) ABSTRACT

A pad conditioner and chemical mechanical planarization (CMP) pad conditioner assembly for a CMP assembly are disclosed. The pad conditioner includes a substrate having a first surface and a second surface opposite the first surface. A plurality of protrusions protrude away from the first surface in a direction that is normal to the first surface. The plurality of protrusions are arranged in a plurality of rows. A first row of the plurality of rows is offset from a second row of the plurality of rows.

### FIELD

This disclosure relates generally to equipment for manufacturing semiconductors. More specifically, this disclosure relates to a pad conditioner for chemical mechanical planarization (CMP).

### BACKGROUND

Chemical mechanical planarization or chemical mechanical polishing (CMP) can be part of the manufacturing process for semiconductor devices. During CMP, material is removed from a wafer substrate via a polishing pad and a polishing slurry. CMP can optionally include one or more chemical reagents. Over time, the polishing pad can become matted and filled with debris. A pad conditioner can be used to recondition the polishing pad.

### SUMMARY

This disclosure relates generally to equipment for manufacturing semiconductors. More specifically, this disclosure relates to a pad conditioner for chemical mechanical planarization (CMP).

A pad conditioner for a chemical mechanical planarization (CMP) assembly is disclosed. The pad conditioner includes a substrate having a first surface and a second surface opposite the first surface. A plurality of protrusions protrude away from the first surface in a direction that is normal to the first surface. The plurality of protrusions are arranged in a plurality of rows. A first row of the plurality of rows is offset from a second row of the plurality of rows.

A chemical mechanical planarization (CMP) pad conditioner assembly is also disclosed. The CMP pad conditioner assembly includes a backing plate having a first backing plate surface and a plurality of pad conditioners secured to the first backing plate surface. Each of the plurality of pad conditioners includes a substrate having a first surface and a second surface opposite the first surface. A plurality of protrusions protrude away from the first surface in a direction that is normal to the first surface. The plurality of protrusions are arranged in a plurality of rows. A first row of the plurality of rows is offset from a second row of the plurality of rows.

### BRIEF DESCRIPTION OF THE DRAWINGS

References are made to the accompanying drawings that form a part of this disclosure, and which illustrate embodiments in which the systems and methods described in this specification can be practiced.

FIG. 1A is a top view of a pad conditioner assembly, according to an embodiment.

FIG. 1B is a sectional view of the pad conditioner assembly of FIG. 1A taken along line 1B-1B, according to an embodiment.

FIG. 2 is a top view of one of the plurality of pad conditioners in FIG. 1A, according to an embodiment.

FIG. 3 is a top view of one of the plurality of pad conditioners in FIG. 1A, according to another embodiment.

Like reference numbers represent like parts throughout.

### DETAILED DESCRIPTION

This disclosure relates generally to equipment for manufacturing semiconductors. More specifically, this disclosure relates to a pad conditioner for chemical mechanical planarization (CMP).

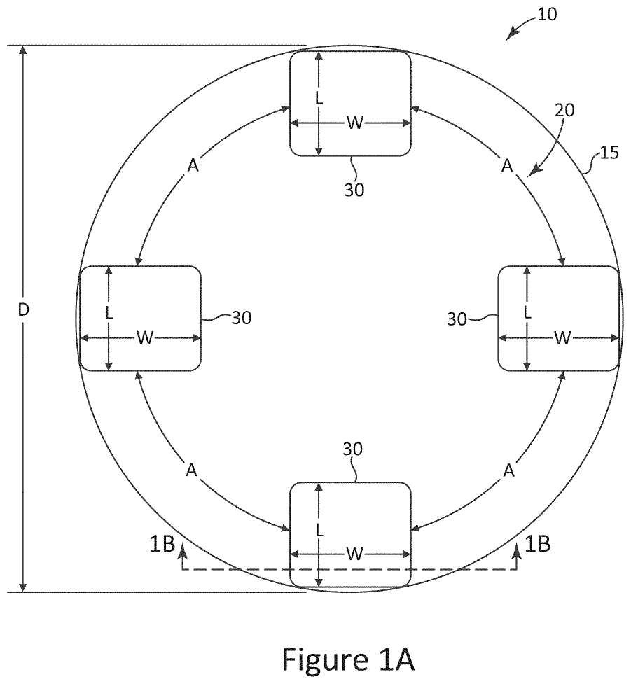

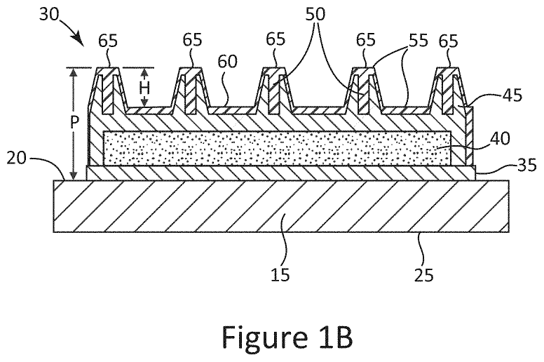

FIG. 1A is a top view of a pad conditioner assembly 10, according to an embodiment. FIG. 1B is a sectional view of the pad conditioner assembly 10 taken along line 1B-1B, according to an embodiment. The pad conditioner assembly 10 can generally be used for reconditioning a polishing pad used in CMP.

The pad conditioner assembly 10 includes a backing plate 15 having a first backing plate surface 20. In an embodiment, the backing plate 15 can have a disc-shape. In an embodiment, the backing plate 15 can alternatively be referred to as the disc-shaped holder 15 or the like. In an embodiment, the first backing plate surface 20 can alternatively be referred to as the first backing plate surface 20. The backing plate 15 has a diameter D. In an embodiment, the diameter D can be between at or about 3 inches to at or about 13 inches. It is to be appreciated that this range is an example and the actual diameter D can be beyond the stated range in accordance with the principles in this Specification. The backing plate 15 can be made of a stainless steel, plastic, or the like.

The backing plate 15 has a second backing plate surface 25 (FIG. 1B) opposite the first backing plate surface 20. The second backing plate surface 25 of the backing plate 15 can include one or more mounting structures (not shown) for securing the backing plate 15 of the pad conditioner assembly 10 to a CMP tool. In an embodiment, the second backing plate surface 25 can be alternatively referred to as the mounting surface 25. The one or more mounting structures can be magnetic, snap-fit, apertures (e.g., for screws, bolts, or the like), or the like. The backing plate 15 can be made of a material that is chemically compatible with the CMP process chemicals and slurry or chemically passivated.

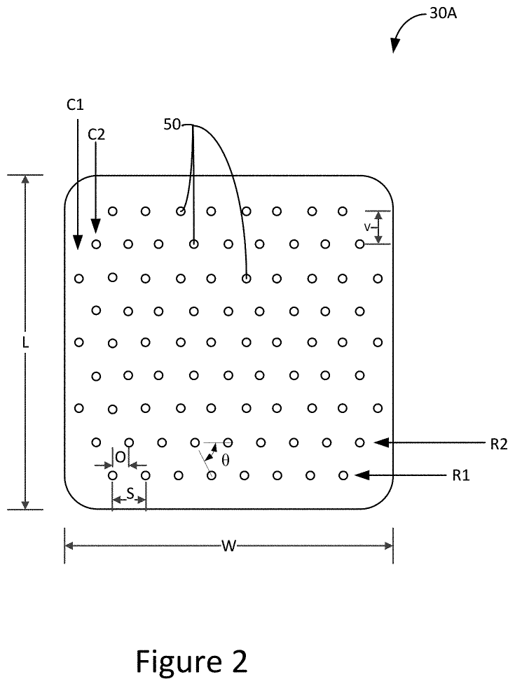

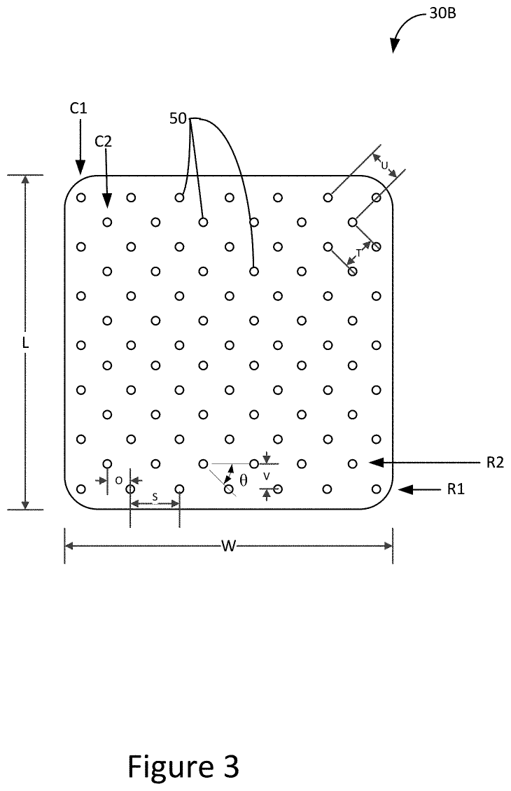

A plurality of pad conditioners 30 are secured to the first backing plate surface 20. Embodiments of the plurality of pad conditioners 30 are shown and described in additional detail with respect to FIGS. 2 and 3 below. It is to be appreciated that the pad conditioners 30 are not drawn to scale in FIG. 1A.

The pad conditioner assembly 10 includes the pad conditioner 30 secured to the first backing plate surface 20 by an adhesive 35. In an embodiment, suitable adhesives can include, but are not limited to, an epoxy, a tape adhesive, or the like.

The pad conditioner 30 can include a core 40 and one or more additional layers. In an embodiment, the core 40 can be secured to the backing plate surface 20 via the adhesive 35. The core 40 can be, for example, a porous silicon carbide or the like. A surface layer 45 is disposed on the core 40. In an embodiment, the surface layer 45 can be a silicon carbide surface layer added to the core 40 via, for example, a chemical vapor deposition process. The surface layer 45 includes a hardened layer 55. The hardened layer 55 can be, for example, a diamond coating that is added to the surface layer 45 via, for example, a chemical vapor deposition. The surface layer 45 and hardened layer 55 are etched (e.g., via a laser or the like) to create a plurality of surface features 50. The plurality of surface features 50 provide the abrasion surface on the pad conditioner 30. As such, when reconditioning a polishing pad for a CMP tool, the surface features 50 contact the polishing pad. In an embodiment, the core 40 and surface layer 45 can collectively be referred to as a substrate.

Each of the plurality of pad conditioners 30 generally provides an abrasive region. The abrasive regions collectively contact a polishing pad used in CMP when reconditioning the polishing pad using the pad conditioner assembly 10. The abrasive region is generally defined by a plurality of contact surfaces.

The various features of the pad conditioners 30 can be configured depending upon the application of the polishing pad being reconditioned using the pad conditioner assembly 10. For example, a relative size of the pad conditioners 30; a number of pad conditioners 30; a feature density on the pad conditioners 30; a depth of the features on the pad conditioners 30; suitable combinations thereof; or the like can be selected based on the application of the polishing pad to be reconditioned.

The pad conditioners 30 each have a length L and a width W. In an embodiment, a ratio of the length L to the width W can be from at or about 0.2 to at or about 1. The length L and the width W can be from at or about 0.1 inches to 3 inches. It is to be appreciated that these ranges are examples and the actual length L, width W, and respective ratio can vary beyond the stated ranges in accordance with the principles of this Specification. In the illustrated embodiment, the pad conditioners 30 are generally square-shaped when viewed from the top view. As used in this Specification, “generally square-shaped” means square-shaped subject to manufacturing tolerances or the like. That is, the length L and the width W of the pad conditioners 30 is substantially the same subject to manufacturing tolerances or the like. In another embodiment, the geometry of the pad conditioners 30 can be a shape other than square. The pad conditioners 30 can include rounded corners and chamfered edges to, for example, minimize an accumulation of material and to, for example, reduce scratching resulting from this accumulation. In an embodiment, the pad conditioners 30 can be rectangular or the like.

In the illustrated embodiment, four pad conditioners 30 are shown. A spacing between the four pad conditioners 30 can be maintained so that an arc length A about the backing plate 15 is equal among all of the pad conditioners 30. In an embodiment, a spacing between the four pad conditioners 30 can be selected so that the arc length A is not equal among all of the pad conditioners 30.

The number of pad conditioners 30 can vary. For example, in an embodiment, more than four pad conditioners 30 can be included on the backing plate 15. Alternatively, fewer than four pad conditioners 30 can be included on the backing plate 15, according to an embodiment. In an embodiment, a minimum number of pad conditioners 30 can be three. Even when the number of pad conditioners 30 varies beyond the illustrated example, the spacing between the pad conditioners 30 can be maintained so that the arc length A about the backing plate 15 remains equal among the pad conditioners 30. Alternatively, the arc length A about the backing plate 15 can be varied among the pad conditioners 30 so that at least one of the arc lengths A is not equal to another of the arc lengths A.

Each of the plurality of pad conditioners 30 include a plurality of protrusions protruding away from the first backing plate surface 20 in a direction that is normal to the first backing plate surface 20. More details of the pad conditioners 30 are discussed in accordance with FIGS. 2 and 3 below.

The surface features 50 can be conical, frustoconical, a combination thereof, or the like. Other geometries for the surface features 50 may be selected. In the illustrated embodiment, the surface features 50 extend from the backing plate 15 a distance P from the first backing plate surface 20 in a direction that is normal to the second backing plate surface 25. Additionally, each of the surface features 50 extend a distance H from the etched surface portion 60 in a direction away from the second backing plate surface 25. The distance H and the distance P can be varied. The distances H and P can be selected based on, for example, an application of the pad conditioner assembly 10 (e.g., the particular polishing pad that will be reconditioned via the pad conditioner assembly 10). The distance H from the etched surface portion 60 can be varied among the surface features 50. For example, a first of the surface features 50 can have extend a first distance H from the etched surface portion 60, while a second of the surface features 50 can extend a second distance from the etched surface portion 60, the second distance being different from the first distance H. In an embodiment, the distance H varies from at or about 15 μm to at or about 100 μm. In an embodiment, the surface features 50 each extend the same distance H so that contact surface 65 is substantially planar.

In an embodiment in which the surface features 50 are frustoconical, the contact surface 65 can be substantially parallel to the first backing plate surface 20 of the backing plate 15. In an embodiment, the contact surface 65 may be a tip of the conical forms of the surface features 50. In such an embodiment, a plane across the tips of the conical forms of the surface features 50 may be substantially parallel to the first backing plate surface 20 of the backing plate 15. In an embodiment in which the distance H is not uniform among the surface features 50, the contact surface 65 may not be planar and may not be parallel to the first backing plate surface 20 of the backing plate 15. As a function of feature tip diameter and geometry, contact surface 65 can be flat and parallel to the first backing plate surface 20. If feature tip diameter is relatively smaller than at or about 50 μm the contact surface 65 may be generally round in shape. The contact surface 65 is the contact point with a polishing pad when the pad conditioner assembly 10 is in use to recondition the polishing pad. Substantially planar, as used herein, is planar subject to manufacturing tolerances or the like.

FIG. 2 is a schematic top view of one of the plurality of pad conditioners 30, according to an embodiment. For simplicity of this description, the one of the plurality of pad conditioners 30 will be referred to as the pad conditioner 30A.

The pad conditioner 30A includes a plurality of surface features 50. In an embodiment, the plurality of surface features 50 have a uniform geometry. That is, each of the surface features 50 is geometrically the same. This can be subject to, for example, manufacturing tolerances or the like. In another embodiment, the plurality of surface features 50 may be geometrically different (i.e., a non-uniform geometry).

The plurality of surface features 50 are provided in a plurality of rows and a plurality of columns. Two of the plurality of rows are labeled R1, R2 and two of the plurality of columns are labeled C1, C2. The remaining rows and columns are not labeled for simplicity of the figure. In the illustrated embodiment, there are nine rows of surface features 50 and there are 19 columns of surface features 50. The number of rows and the number of columns of surface features 50 can vary. In the illustrated embodiment, the number of columns of surface features 50 is greater than the number of rows of surface features 50. In an embodiment, this could be reversed so that the number of rows of surface features 50 is greater than the number of columns of surface features 50. In an embodiment, the number of rows of surface features 50 can be the same as the number of columns of surface features 50. Such an embodiment is shown and described with reference to FIG. 3 below.

The surface features 50 in row R1 are offset from the surface features 50 in row R2. In the illustrated embodiment, the offset is shown as a distance O. The distance O is representative of the spacing between columns. That is, the distance O is equal to the spacing between the column C1 and the column C2 of surface features 50. The spacing between the surface features 50 within a row is shown as a distance S. In the illustrated embodiment, the distance S is representative of a horizontal spacing and a distance V is representative of a vertical spacing (with respect to the page). The distance S and the distance V are the same in FIG. 2. In an embodiment, the distance S and the distance V can vary. In an embodiment, the distance S and the distance V may not be uniform across an entire surface of the pad conditioner 30A.

The distance O can be up to at or about half the distance S. In the illustrated embodiment, the distance O can range from about 0.1 to 0.5S. In one embodiment, the distance O is 0.5S.

An angle θ is shown representing an angle between the row R2 and the surface features 50 in the row R1. The angle θ can vary as the offset between the rows R1 and R2 varies. In an embodiment, θ can range from at or about 10° to at or about 60° or more particularly, θ can range from at or about 35° to at or about 55°. In an embodiment, the angle θ is at or about 45°. A lower angle θ is representative of a larger offset between the surface features 50 in row R1 and the surface features 50 in row R2 while a relatively larger angle θ is representative of a smaller offset between the surface features 50 in row R1 and the surface features 50 in row R2.

A density of the surface features 50 can vary in the conditioner pad 30A. For example, if the distance S, the distance V, or combinations thereof, is decreased, then the conditioner pad 30A can include additional surface features 50. Conversely, if the distance S, the distance V, or combinations thereof, is increased, then the conditioner pad 30A can include fewer surface features 50. In an embodiment, a density of the surface features 50 can range from at or about 0.10 per mm² to at or about 25 per mm² or more particularly, a density of the surface features 50 can range from at or about 0.25 per mm² to at or about 15 per mm².

The surface features 50 in a single row (e.g., R1) are aligned in a horizontal direction with respect to the page. The rows (e.g., R1 and R2) of surface features 50 are substantially parallel to each other. As used in this Specification, “substantially parallel” means parallel subject to manufacturing tolerances or the like. The surface features 50 in a single row (e.g., R1) are uniformly spaced (the distance S).

The surface features 50 in a single column (e.g., C1) are aligned in a vertical direction with respect to the page. The columns (e.g., C1 and C2) of surface features are substantially parallel to each other. In the illustrated embodiment, a spacing between the rows (e.g., the distance V) and a spacing between the columns (e.g., the distance O) is constant across the conditioner pad 30A. The surface features 50 in a single column (e.g., C1) are uniformly spaced (the distance V). In an embodiment, the spacing between the rows (e.g., the distance V) and the spacing between the columns (e.g., the distance O) may not be constant across the conditioner pad 30A. In an embodiment, the surface features 50 in a single column (e.g., C1) may have a varying spacing (i.e., non-uniformly spaced (the distance V)).

The columns, the rows, or both the columns and the rows can have a variable spacing. In an embodiment, a ratio of the number of columns to the number of rows is from at or about 0.2 to at or about 1.

FIG. 3 is a schematic top view of one of the plurality of pad conditioners 30, according to another embodiment. For simplicity of this description, the one of the plurality of pad conditioners 30 will be referred to as the pad conditioner 30B. The pad conditioner 30B has a different density of the surface features 50 than the density of the surface features 50 in the pad conditioner 30A of FIG. 2.

The pad conditioner 30B includes a plurality of surface features 50. In an embodiment, the plurality of surface features 50 have a uniform geometry. That is, each of the surface features 50 is geometrically the same. This can be subject to, for example, manufacturing tolerances or the like. In another embodiment, the plurality of surface features 50 may be geometrically different (i.e., a non-uniform geometry).

The plurality of surface features 50 are provided in a plurality of rows and a plurality of columns. Two of the plurality of rows are labeled R1, R2 and two of the plurality of columns are labeled C1, C2. The remaining rows and columns are not labeled for simplicity of the figure. In the illustrated embodiment, there are nine rows of surface features 50. The number of rows of surface features 50 can vary.

The surface features 50 in row R1 are offset from the surface features 50 in row R2. In the illustrated embodiment, the offset is shown as a distance O. The distance O is representative of spacing between columns. That is, the distance O is equal to the spacing between the column C1 and the column C2 of surface features 50. The spacing between the surface features 50 within a row is shown as a distance S. In the illustrated embodiment, the distance S is representative of a horizontal spacing and a distance V is representative of a vertical spacing (with respect to the page). The distance S and the distance V are the same in FIG. 3. In an embodiment, the distance S and the distance V can vary. In an embodiment, the distance S and the distance V may not be uniform across an entire surface of the pad conditioner 30B.

The distance O can be up to at or about half the distance S.

An angle θ is shown representing an angle between the row R2 and the surface features 50 in the row R1. The angle θ can vary as the offset between the rows R1 and R2 varies. In an embodiment, θ can range from at or about 10° to at or about 60° or more particularly, θ can range from at or about 35° to at or about 55°. In an embodiment, the angle θ is at or about 45°. A lower angle θ is representative of a larger offset between the surface features 50 in row R1 and the surface features 50 in row R2 while a relative larger angle θ is representative of a smaller offset between the surface features 50 in row R1 and the surface features 50 in row R2.

A density of the surface features 50 can vary in the conditioner pad 30B. For example, if the distance S, the distance V, or combinations thereof, is decreased, then the conditioner pad 30B can include additional surface features 50. Conversely, if the distance S, the distance V, or combinations thereof, is increased, then the conditioner pad 30B can include fewer surface features 50. In an embodiment, a density of the surface features 50 can range from at or about 0.10 per mm² to at or about 25 per mm² or more particularly, from at or about 0.25 per mm² to at or about 15 per mm².

In the illustrated embodiment, a distance T and a distance U, measured from a surface feature 50 in a first row to surface feature 50 in a second row that is offset from the first surface feature 50 is T, and from a surface feature 50 in a third row to the surface feature 50 in the second row is U. The distances U and T in the illustrated figure are equal, but can vary so that the distances are not equal, according to another embodiment.

Aspects

It is noted that any of aspects 1-13 can be combined with any one of aspects 14-22.

Aspect 1. A pad conditioner for a chemical mechanical planarization (CMP) assembly, comprising: a substrate having a first surface and a second surface opposite the first surface; and a plurality of protrusions protruding away from the first surface in a direction that is normal to the first surface, wherein the plurality of protrusions are arranged in a plurality of rows, wherein a first row of the plurality of rows is offset from a second row of the plurality of rows.

Aspect 2. The pad conditioner of aspect 1, wherein the plurality of protrusions include a uniform geometry.

Aspect 3. The pad conditioner of aspect 2, wherein the plurality of protrusions include one of conical and frustoconical.

Aspect 4. The pad conditioner of any one of aspects 1-3, wherein the plurality of protrusions are uniformly spaced.

Aspect 5. The pad conditioner of any one of aspects 1-4, wherein the plurality of protrusions are formed of a silicon carbide having a diamond coated cutting surface.

Aspect 6. The pad conditioner of any one of aspects 1-5, wherein a density of the plurality of protrusions is from at or about 0.10 per mm² to at or about 25 per mm² or from about 0.25 per mm² to at or about 15 per mm².

Aspect 7. The pad conditioner of any one of aspects 1-6, wherein a protrusion distance from the substrate is from at or about 15 μm to at or about 100 μm.

Aspect 8. The pad conditioner of any one of aspects 1-7, wherein the offset is from at or about 10° to at or about 60° or from at or about 35° to at or about 55°.

Aspect 9. The pad conditioner of any one of aspects 1-8, wherein the offset is at or about 45°.

Aspect 10. The pad conditioner of any one of aspects 1-9, wherein a number of protrusions in the first row of the plurality of protrusions is different than a number of protrusions in the second row of the plurality of protrusions.

Aspect 11. The pad conditioner of any one of aspects 1-10, wherein a number of rows in the plurality of rows is different from a number of protrusions in the row.

Aspect 12. The pad conditioner of any one of aspects 1-11, wherein the plurality of protrusions are integrally formed in the substrate.

Aspect 13. The pad conditioner of any one of aspects 1-12, wherein the first row of the plurality of rows includes a same number of protrusions as a number of the plurality of columns.

Aspect 14. A chemical mechanical planarization (CMP) pad conditioner assembly, comprising: a backing plate having a first backing plate surface; and a plurality of pad conditioners secured to the first backing plate surface, each of the plurality of pad conditioners comprising: a substrate having a first surface and a second surface opposite the first surface; and a plurality of protrusions protruding away from the first surface in a direction that is normal to the first surface, wherein the plurality of protrusions are arranged in a plurality of rows, wherein a first row of the plurality of rows is offset from a second row of the plurality of rows.

Aspect 15. The assembly of aspect 14, wherein the plurality of pad conditioners are spaced circumferentially about the backing plate.

Aspect 16. The assembly of aspect 14 or 15, wherein each of the plurality of pad conditioners is the same.

Aspect 17. The assembly of any one of aspects 14-16, wherein the plurality of protrusions include a uniform geometry.

Aspect 18. The assembly of aspect 15, wherein the plurality of protrusions are one of conical and frustoconical.

Aspect 19. The assembly of any one of aspects 14-18, wherein the plurality of protrusions are uniformly spaced.

Aspect 20. The assembly of any one of aspects 14-19, wherein the plurality of protrusions are formed of a silicon carbide having a diamond coated cutting surface formed by a chemical vapor deposition.

Aspect 21. The assembly of any one of aspects 14-20, wherein a density of the plurality of protrusions is from at or about 0.10 per mm² to at or about 25 per mm² or from at or about 0.25 per mm² to at or about 15 per mm².

Aspect 22. The assembly of any one of aspects 14-21, wherein the offset is at or about 45°.

The terminology used in this specification is intended to describe particular embodiments and is not intended to be limiting. The terms “a,” “an,” and “the” include the plural forms as well, unless clearly indicated otherwise. The terms “comprises” and/or “comprising,” when used in this specification, specify the presence of the stated features, integers, steps, operations, elements, and/or components, but do not preclude the presence or addition of one or more other features, integers, steps, operations, elements, and/or components.

With regard to the preceding description, it is to be understood that changes may be made in detail, especially in matters of the construction materials employed and the shape, size, and arrangement of parts without departing from the scope of the present disclosure. This specification and the embodiments described are exemplary only, with the true scope and spirit of the disclosure being indicated by the claims that follow.

What is claimed is:

1. A pad conditioner for a chemical mechanical planarization (CMP) assembly, comprising:
a substrate having a first surface and a second surface opposite the first surface; and
a plurality of protrusions protruding away from the first surface in a direction that is normal to the first surface, wherein the plurality of protrusions are arranged in a plurality of rows,
wherein a first row of the plurality of rows is offset from a second row of the plurality of rows.

2. The pad conditioner of claim 1, wherein the plurality of protrusions include a uniform geometry.

3. The pad conditioner of claim 2, wherein the plurality of protrusions include one of conical and frustoconical.

4. The pad conditioner of claim 1, wherein the plurality of protrusions are uniformly spaced.

5. The pad conditioner of claim 1, wherein the plurality of protrusions are formed of a silicon carbide having a diamond coated cutting surface.

6. The pad conditioner of claim 1, wherein a density of the plurality of protrusions is from at or about 0.10 per mm² to at or about 25 per mm².

7. The pad conditioner of claim 1, wherein a protrusion distance from the substrate is from at or about 15 μm to at or about 100 μm.

8. The pad conditioner of claim 1, wherein the offset is from at or about 10° to at or about 60°.

9. The pad conditioner of claim 1, wherein the offset is at or about 45°.

10. The pad conditioner of claim 1, wherein a number of protrusions in the first row of the plurality of protrusions is different than a number of protrusions in the second row of the plurality of protrusions.

11. The pad conditioner of claim 1, wherein the plurality of rows includes a third row, the third of the plurality of rows being offset from the second of the plurality of rows.

12. A chemical mechanical planarization (CMP) pad conditioner assembly, comprising:
a backing plate having a first backing plate surface; and
a plurality of pad conditioners secured to the first backing plate surface, each of the plurality of pad conditioners comprising:
a substrate having a first surface and a second surface opposite the first surface; and
a plurality of protrusions protruding away from the first surface in a direction that is normal to the first surface, wherein the plurality of protrusions are arranged in a plurality of rows,
wherein a first row of the plurality of rows is offset from a second row of the plurality of rows.

13. The assembly of claim 12, wherein the plurality of pad conditioners are spaced circumferentially about the backing plate.

14. The assembly of claim 12, wherein each of the plurality of pad conditioners is the same.

15. The assembly of claim 12, wherein the plurality of protrusions include a uniform geometry.

16. The assembly of claim 15, wherein the plurality of protrusions are one of conical and frustoconical.

17. The assembly of claim 12, wherein the plurality of protrusions are uniformly spaced.

18. The assembly of claim 12, wherein the plurality of protrusions are formed of a silicon carbide having a diamond coated cutting surface formed by a chemical vapor deposition.

19. The assembly of claim 12, wherein a density of the plurality of protrusions is from at or about 0.10 per mm² to at or about 25 per mm².

20. The assembly of claim 12, wherein the offset is at or about 45°.
